(19) United States
(12) Patent Application Publication
(10) Pub. No.: US 2010/0314778 A1
(43) Pub. Date: Dec. 16, 2010

(54) SEMICONDUCTOR DEVICE AND METHOD FOR PRODUCING THE SAME

(75) Inventors: Hideya Murai, Tokyo (JP); Kentaro Mori, Tokyo (JP); Shintaro Yamamichi, Tokyo (JP); Masaya Kawano, Kanagawa (JP); Kouji Soejima, Kanagawa (JP)

Correspondence Address: SUGHRUE MION, PLLC, 2100 PENNSYLVANIA AVENUE, N.W., SUITE 800, WASHINGTON, DC, 20037, US

(73) Assignees: NEC CORPORATION, Minato-ku, Tokyo (JP); RENESAS ELECTRONICS CORPORATION, Kawasaki, Kanagawa (JP)

(21) Appl. No.: 12/867,721

(22) PCT Filed: Feb. 6, 2009
(86) PCT No.: PCT/JP2009/052067

§ 371 Date: Aug. 13, 2010

(30) Foreign Application Priority Data
Feb. 14, 2008 (JP) 2008-033305

(51) Int. Cl. H01L 23/48; H01L 21/768

(52) U.S. Cl. 257/774; 438/675; 257/E23.011; 257/E21.577

(57) ABSTRACT

In forming a semiconductor device, an insulation layer is formed on top of a semiconductor chip having a plurality of external terminals. A plurality of interconnections is formed on the insulating layer. External terminals are electrically connected to coordinated interconnections through a plurality of vias formed in the insulation layer. The interconnections are each formed integral with a via conduction part which covers the entire surfaces of the bottom and the sidewall sections of the via. The interconnection is formed so as to be narrower in its region overlying the via than the upper via diameter.

### TECHNICAL FIELD

### Reference to Related Application

This application is based upon and claims the benefit of the priority of Japanese patent application No. 2008-033305 filed on Feb. 14, 2008, the disclosure of which is incorporated herein in its entirety by reference thereto.

This invention relates to a semiconductor device having a semiconductor chip embedded in a wiring substrate or base, and a method for producing the same. More particularly, it relates to a semiconductor device which lends itself to connection at a narrow pitch, and a method for producing the same.

### BACKGROUND

Recently, a semiconductor device having a semiconductor chip embedded in a wiring substrate or base, and a semiconductor device in which an insulating resin layer and an interconnection layer are directly formed on the semiconductor chip, viz., without interposition of bumps, are attracting the attention. The former semiconductor device is termed an integrated chip board. The semiconductor chip, such as LSI chip, has been cut from a wafer as a small size segment. The integrated chip board is prepared by embedding the semiconductor chip in an insulation layer, forming a via in the insulation layer, and by depositing an interconnection configured for being electrically connected to an external terminal of the semiconductor chip through the via. When the interconnection is formed after forming the via, it is necessary to cope with the problem of offset of a resist mask used in forming the interconnection. To this end, a land 106a, having a diameter greater than the via diameter at the upper via portion (via upper diameter), is routinely formed to cover the via 105a in its entirety at the foremost part of the interconnection 106 (see FIG. 12).

On the other hand, the semiconductor chip has been improved in performance in these days. The number of external terminals of the semiconductor chip tends to increase, and hence the pitch of the external terminals is becoming narrower. In an integrated chip board, there is a demand for integration or mounting of the semiconductor chips at a narrow pitch. However, the interval between the vias 105a needs to be larger than the sum of the diameter of the land 106a and the land-to-land distance large enough to provide for sufficient insulation performance. There is thus raised a problem that, in case of a large land size, it is difficult to get semiconductor chips with the narrow pitch of the external terminals 104 integrated in the board (see FIG. 13). Among the methods for coping with the land-related problem, there is known a connection configuration in which connection to an external terminal 204 on the via bottom is solely by a landless interconnection (trace) 206, as shown in FIG. 14. In this configuration, since the interconnection 206 has no land, it is possible to provide for narrow-pitch connection limited solely by the diameter of the via 205a.

As another known land-free configuration, there is shown in Patent Document 1 a multi-layer wiring board 301, in which a via hole conductor 304 is composed of metal powders charged in a via hole, and a conductor interconnection layer 303, formed by a metal foil, is connected to the via hole conductor 304. The conductor interconnection layer 303 is embedded within the bulk of the via-hole conductor 304 with a line width narrower than the diameter of the via hole of the via hole conductor 304 (see FIG. 15).

### Patent Document 1:

JP Patent Kokai Publication No. JP-A-11-103165 (FIG. 1)

### SUMMARY

The disclosure of the Patent Document 1 is to be incorporated by reference herein. The following is an analysis of the related techniques by the present invention.

The above described prior art technique is beset with the following problems.

In the connection configuration by only the landless interconnection 206, shown in FIG. 14, the connection area between the interconnection 206 and the external terminal 204 of the semiconductor chip 201 becomes smaller. Hence, the probability of occurrence of connection failures becomes higher, with the result that the yield is lowered. Since the contact area is small, the tolerance for position misregistration between the interconnection 206 and the external terminal 204 of the semiconductor chip 201 is reduced. Even though the interconnection 206 is initially connected to the external terminal 204 of the semiconductor chip 201, the interconnection 206 tends to peel off from the external terminal 204 of the semiconductor chip 201 at an interfacing area due to, for example, the stress produced by temperature variations that may arise during the subsequent operation of the semiconductor chip 201, or to heat cyclic tests, resulting in disconnections. Viz., sufficient interconnection reliability may not be obtained. Such peeling on the interface may be outstanding when the semiconductor device, such as LSI package, is connected to another device, such as a motherboard, as its component part, since the stress generated is then increased.

Further, in case of a configuration in which the interconnection 206 is connected to the external terminal 204 of the semiconductor chip 201 only at a via bottom, as shown in FIG. 14, there is raised a problem that the external terminal 204 of the semiconductor chip 201 is partially exposed to outside. In this case, there is presented a problem that the LSA layer 203 at the via bottom, carrying semiconductor devices, not shown, may not be protected sufficiently. The LSI layer 203 in the semiconductor chip 201 has only low resistance against metal impurities, such as copper atoms, or ionic impurities, such as sodium ions. These impurities may readily be intruded into the inside of the LSI layer 203, thus possibly damaging it. If these impurities are contacted with the external terminal, an ultimate product may be deteriorated in reliability. It is observed that the impurities may be contacted with the external terminal 204 of the semiconductor chip 201 of the ultimate product not only in case the external terminal is exposed to outside in the ultimate product, but also in case the external terminal, not exposed in the ultimate product, is exposed in intermediate process steps.

Moreover, in an integrated chip board, it is a frequent occurrence that an inexpensive printed wiring substrate not high in cleanliness is used for manufacturing the board. In this case, the probability of impurity intrusion becomes further higher, such that, in a configuration in which the external terminal 204 of the semiconductor chip 201 is exposed to outside, as in FIG. 14, the problem of impurity intrusion into a further inner region of the LSI layer 203 may be more pronounced. Among the impurities that possibly affect the LSI layer 203, there are, for example, liquid agents, such as an etching solution used for etching an interconnection seed layer, and a liquid drug, e.g., a desmear solution used for roughening the surface of the insulation resin layer. It is observed that, in the configuration of FIG. 14, the interconnection may be of a broader width such that the external terminal 204 of the semiconductor chip 201 is not completely exposed to outside. Even in such case, the probability of the impurities passing through the interface between the insulation layer 205 and the interconnection 206 to affect the LSI layer 203 is higher than in case the via in its entirety is covered with the land 106a, as in FIG. 12, thus possibly lowering the yield.

On the other hand, in a configuration of Patent Document 1 (see FIG. 15), the conductor interconnection layer 303 is subsequently formed over the via hole conductor 304, obtained on charging metal powders. Hence, the connection between the via hole conductor 304 and the conductor interconnection layer 303 may not be sufficient with the result that peel-off or the like flaws tend to be produced on the interface between the via hole conductor 304 and the conductor interconnection layer 303. In particular, if a thermal stress due to heat cyclic tests or a mechanical stress due to connection to outside is generated, such shortage of the bonding power between the via hole conductor 304 and the conductor interconnection layer 303 may be problematical. In addition, in the configuration of the related art technique, metal powders are used in the via hole conductor 304. It is thus difficult to reduce the resistance of the via hole conductor 304 itself or that of the interface between the via hole conductor 304 and the conductor interconnection layer 303. Because of the high resistance, the problem of driving failures may be presented in case a semiconductor chip for a high frequency operation is embedded in the board for raising the resistance. It is observed that the via hole conductor 304, containing the metal powders, are compressed from above with a strong force, such as that of a press, in order to form an insulation layer 302. Thus, if a relatively fragile material, such as low-k material, is used as a semiconductor chip material, the probability is high that failures may be produced due to mechanical stresses generated in the embedment process or in subsequent reliability tests.

It is a principal object of the present invention to provide a semiconductor device that allows for connection with a narrow via pitch and that has a high yield with a high reliability, and a method for manufacturing the semiconductor device.

In a first aspect, the present invention provides a semiconductor device in which an insulation layer is formed on a semiconductor chip having a plurality of external terminals, a plurality of interconnections are formed on the insulation layer, and in which the external terminals and those interconnections that are coordinated to the external terminals are electrically connected to each other through a plurality of vias formed in the insulation layer. A via conduction part is formed so that, in the inside of the via, the via conduction part is formed so as to cover the entire surfaces of a bottom and a sidewall section of the via. The via conduction part is formed integral with the interconnection. The portion of the interconnection overlying the via is smaller in size than the diameter of an upper part of the via.

In a second aspect, the present invention provides a method for manufacturing a semiconductor device, in which the method comprises the steps of forming an insulation layer on a semiconductor chip having a plurality of external terminals, forming a plurality of vias in the insulation layer for connecting to the external terminals, forming a resist layer having an opening part for an interconnection on the insulation layer, with the width of the opening part for the interconnection overlying the via being lesser than the diameter of an upper part of the via, and forming the via conduction part and the interconnection integral with each other on the insulation layer, using a resist layer as a mask, so that the via conduction part and the interconnection will cover the bottom surface and the sidewall sections of the via.

According to the present invention, there may be provided a semiconductor device of a high yield and high reliability in which the pitch of connection of the semiconductor chip may be reduced. Hence, the semiconductor chip with the reduced pitch of connection of the external terminals may be used, so that a semiconductor device may be of a high yield and high reliability. With the configuration proposed by the present invention, the mechanical stress generated in the via may be relaxed further to provide for improved operational reliability of the semiconductor device.

### BRIEF DESCRIPTION OF THE DRAWINGS

FIG. 1 is a schematic cross-sectional view showing the configuration of a semiconductor device according to Example 1 of the present invention, with an interconnection thereof being shown in a schematic top plan view.

FIG. 2 is a schematic top plan view showing certain example interconnection patterns of the semiconductor device according to Example 1 of the present invention.

FIG. 3 is a schematic top plan view showing a modification of the interconnection pattern of the semiconductor device according to Example 1 of the present invention.

FIG. 4 is a schematic cross-sectional view showing the configuration of the semiconductor device according to the modification of Example 1 of the present invention, with an interconnection thereof being shown in a schematic top plan view.

FIG. 5 is a schematic cross-sectional view showing the configuration of the semiconductor device according to the modification of Example 1 of the present invention.

FIGS. 6A to 6D are cross-sectional views for a first process showing a method for manufacturing the semiconductor device according to Example 1 of the present invention.

FIGS. 7A to 7C are cross-sectional views for a second process showing the method for manufacturing the semiconductor device according to Example 1 of the present invention.

FIGS. 8A and 8B are top plan views showing the relationship between an interconnection and a via of a semiconductor device according to Example 2 of the present invention.

FIGS. 9A and 9B are top plan views showing the relationship between an interconnection and a via of a semiconductor device according to Example 3 of the present invention.

FIGS. 10A and 10B are top plan views showing the relationship between an interconnection and a via of a semiconductor device according to Example 3 of the present invention.

FIGS. 11A and 11B are top plan views showing the relationship between an interconnection and a via of a semiconductor device according to Example 4 of the present invention.

FIG. 12 is a schematic cross-sectional view showing the configuration of a semiconductor device according to a related art example 1, with an interconnection thereof being shown in a schematic top plan view.

FIG. 13 is a top plan view schematically showing the configuration of an interconnection, a land and a via in the semiconductor device according to the related art example 1.

FIG. 14 is a schematic cross-sectional view showing the configuration of a semiconductor device according to a related art example 2, with an interconnection thereof being shown in a top plan view.

FIG. 15 is a schematic cross-sectional view showing the configuration of a multilayer wiring board semiconductor device according to a related art example 3.

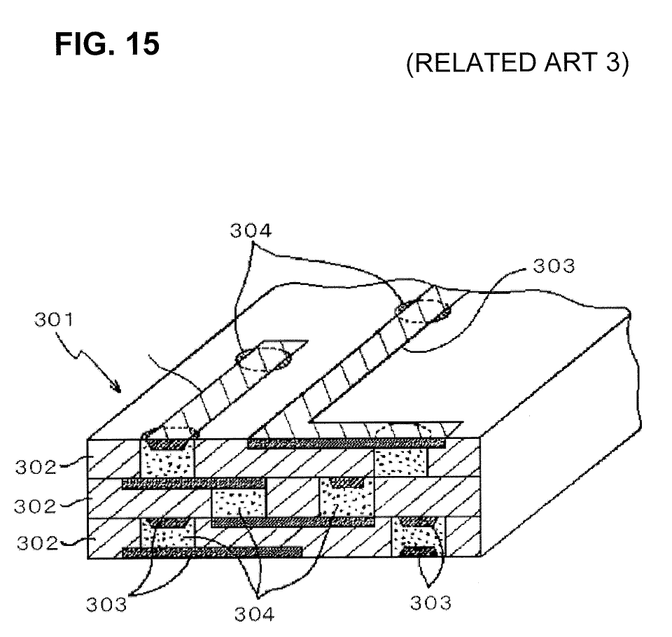

### EXPLANATIONS OF SYMBOLS

Refer to the end of disclosure

### PREFERRED MODES

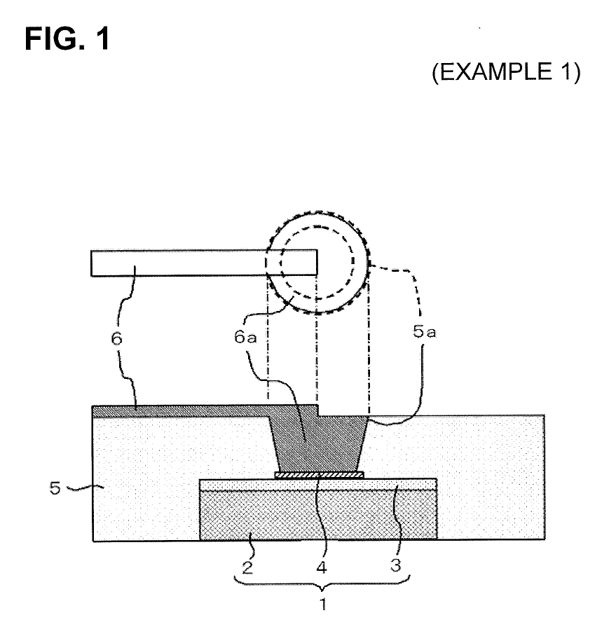

In a semiconductor device according to an exemplary embodiment of the present invention, an insulation layer (5 of FIG. 1) is formed on a semiconductor chip (1 of FIG. 1) having a plurality of external terminals (4 of FIG. 1), and a plurality of interconnections (wiring traces 6 of FIG. 1) are formed on the insulation layer (5 of FIG. 1). The external terminals (4 of FIG. 1) and the interconnections (6 of FIG. 1) that are coordinated thereto are electrically connected to each other through a plurality of vias (5a of FIG. 1) opened in the insulation layer (5 of FIG. 1). A via conduction part (6a of FIG. 1) is formed so that, in the inside of each via (5a of FIG. 1), the via conduction part covers the entire surfaces of a bottom and a sidewall section of the via. The via conduction part is formed integral with the interconnection (6 of FIG. 1). The portion of the interconnection (6 of FIG. 1) overlying the via is smaller in size than the diameter of an upper part of the via.

The following configuration is also possible:

The peripheral part of the via on the insulation layer is preferably devoid of a land.

Preferably, the via conduction part completely fills the inside of the via.

Preferably, the portion of the interconnection (wiring trace) overlying the via is circular or elliptical, with the diameter or the long diameter of the circle or the ellipsis being lesser than the diameter of the upper part of the via.

Preferably, the diameter of the circle or the long diameter of the ellipsis is not lesser than one-third and not larger than two-thirds of the diameter of the upper part of the via.

Preferably, the distal end of the interconnection overlying the via is not extended to the center of the via.

Preferably, one or more protrusions are formed integral with the via conduction part. Preferably, the protrusion(s) is (are) separated from the distal end of the interconnection overlying the via.

Preferably the via has the shape of an ellipsis, an oval shape or a shape of a plurality of circles (or partial circles) concatenated together.

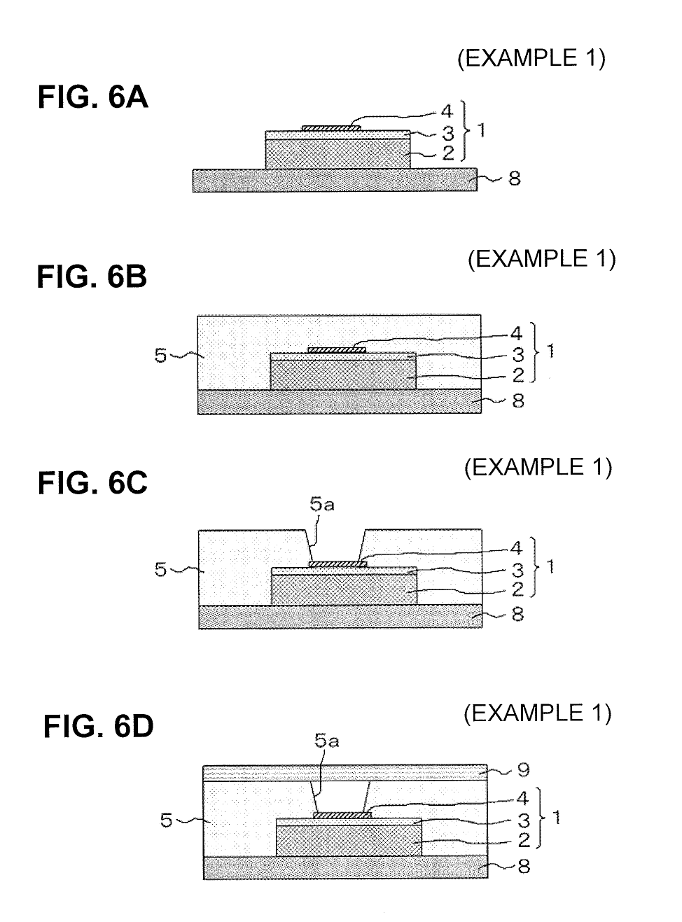

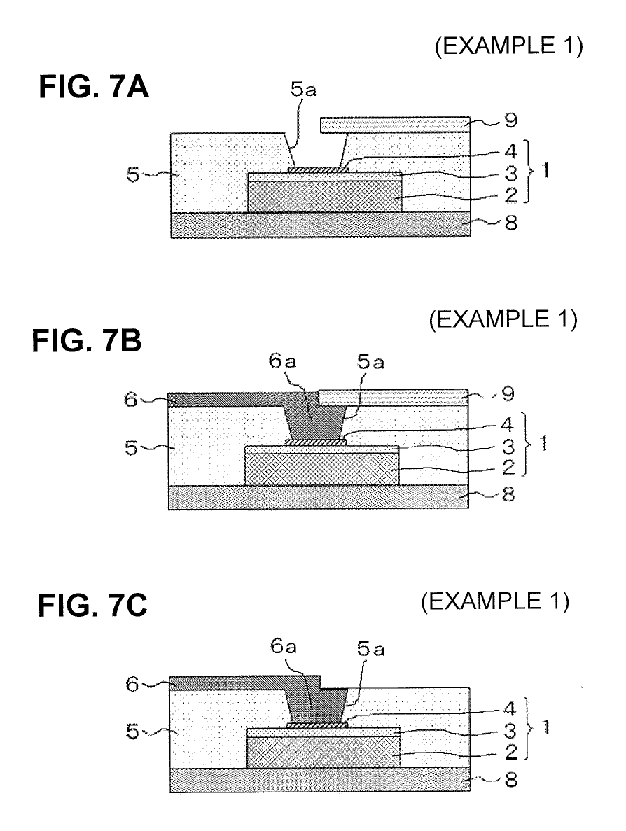

A method for manufacturing a semiconductor device in an exemplary embodiment of the present invention comprises the steps of forming an insulation layer (5 of FIG. 6B) on a semiconductor chip (1 of FIG. 6B) having a plurality of external terminals (4 of FIG. 6B), forming a plurality of vias (5a of FIG. 6C) in the insulation layer (5 of FIG. 6C) for connecting to the external terminals (4 of FIG. 6C), forming a resist layer (9 of FIG. 7A) having a plurality of opening parts for interconnections on the insulation layer (5 of FIG. 7A), with the width of each of the opening parts for the interconnections overlying the via (5a of FIG. 7A) being lesser than the diameter of an upper part of the via, and forming the via conduction parts (6a of FIG. 7B) and the interconnections (6 of FIG. 7B) integral with each other on the insulation layer (5 of FIG. 7B), using the resist layer (9 of FIG. 7B) as a mask, so that the via conduction parts and the interconnections will cover the bottom surface and the sidewall sections of the vias.

Additionally, the following configurations are also possible:

Preferably, a film-like resist is used in the resist layer forming step to form the resist layer.

Preferably, the opening part for the interconnection in the resist layer overlying the via is circular or elliptical and is so formed that the diameter of the circle or the diameter of the ellipses will be lesser than the diameter of the upper part of the via.

Preferably, in the step of forming the resist layer, the opening part for the interconnection in the resist layer overlying the via is formed so that the diameter of the circle or the diameter of the ellipses will be not less than one-third and not more than two-thirds of the diameter of the upper part of the via.

Preferably, the opening part for the interconnection in the resist layer overlying the via is not extended to the center of the via.

Preferably, in the step of forming the resist layer, the opening part for the interconnection of the resist layer overlying the via is formed so that the opening part will be isolated from an opening part connecting to an opening part for the interconnection in the resist layer on the insulation layer.

Preferably, in the step of forming the resist layer, the opening part for the interconnection in the resist layer overlying the via is formed so as to present a plurality of regions.

Preferably, in the step of forming the via, the via is formed so that the plan shape thereof will be elliptical, oval-shaped or composed of a plurality of circles (or partial circles) concatenated together.

### Example 1

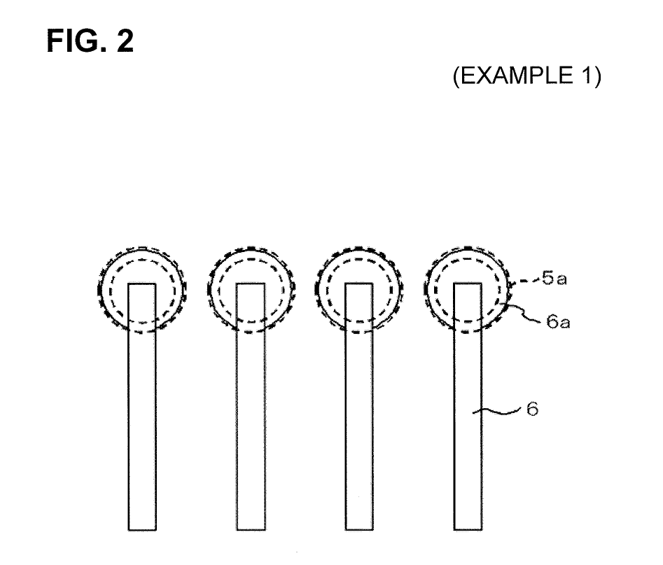

A semiconductor device according to Example 1 of the present invention will now be described with reference to the drawings. FIG. 1 depicts a schematic cross-sectional view showing a semiconductor device according to Example 1 of the present invention, with an interconnection being shown in an upper plan view. FIG. 2 depicts a schematic plan view showing an example interconnection pattern of the semiconductor device according to Example 1 of the present invention. Although larger numbers of vias 5a are actually provided in the semiconductor chip 1, only one via is shown in FIG. 1.

In the semiconductor device of Example 1, an insulation layer 5 is provided on a semiconductor chip 1 having an external terminal 4, and an interconnection 6 is formed on the insulation layer 5. A plurality of vias 5a is formed in the insulation layer 5 in the semiconductor device. A via conduction part 6a, formed of an electrically conductive material for electrically interconnecting the external terminal 4 of the semiconductor chip 1 and the interconnection 6, is charged in the via 5a. The via conduction part 6a is formed for covering substantially the entire via bottom surface and substantially the entire sidewall section of the via. In the semiconductor device, the width of the interconnection 6 is lesser than the upper via diameter. The interconnection 6 is formed integral (solid) with the via conduction part 6a.

The via upper diameter is the diameter of an upper part of the via 5a. In case the via has been formed by laser working, light exposure and development, for example, the upper part of the via is normally greater in diameter than the via bottom. However, this is not to be interpreted restrictively. The term ‘being formed integral’ denotes being formed in one process step by, for example, plating, and denotes that there is no interface between the interconnection 6 and the via conduction part 6a.

The semiconductor chip 1 is made up of a semiconductor layer 2, a semiconductor device, such as LSI, formed on the semiconductor layer (LSI layer 3) and an external terminal 4 formed at a preset location on the LSI layer 3. The semiconductor chip 1 is obtained by forming the sole main LSI layer 3 at a time on a semiconductor wafer and cutting the resulting wafer into individual segments such as by dicing. Although the external terminal 4 is also deposited on the wafer before dicing, it may be deposited after dicing. The external terminal 4 is used for electrically connecting the LSI layer 3, built in the vicinity of the chip surface, to outside, and is also termed a semiconductor pad. The external terminal 4 is connected to a power supply, to the ground or to a signal. The external terminal 4 may be formed mainly of Al or Cu, only by way of illustration.

The insulation layer 5 may be formed of, for example, a non-photosensitive material or a photosensitive material. A ceramic material may also be used. A sheet-shaped resin material, used for the insulation layer 5, is mostly a non-photosensitive material. This non-photosensitive material is routinely used as a sheet-shaped insulation material for a printed wiring board. Hence, it is manufactured in large quantities and hence at low cost. The non-photosensitive material or the photosensitive material may contain an inorganic filler, such as a silica filler, or an organic filler.

In case the insulation layer 5 is formed of the non-photosensitive material, the via 5a may be formed on laser light illumination. The via 5a may also be formed by drilling. In particular, if the insulation layer 5 is formed of the non-photosensitive material, it is customary to use laser light to form the via 5a. As the laser light used in forming the via, an Nd-YAG laser or a CO₂ laser may be used. Or, an excimer laser may also be used. Since the via 5a, formed in the semiconductor chip 1, is small in comparison with the via used in a printed wiring board, the Nd-YAG laser (third harmonics) or the excimer laser, capable of forming a via less than tens of μm, is most preferred. If the insulation layer 5 is formed of the photosensitive material, the via 5a may be formed by the process of light exposure and development. With the process of light exposure and development, a fine via 5a may be formed.

A plating material, such as copper, may be used for forming the interconnection 6 inclusive of the via conduction part 6a. The interconnection 6 may be single-layered or multi-layered. An uppermost layer may be provided with a resin layer that covers at least a portion of the interconnection.

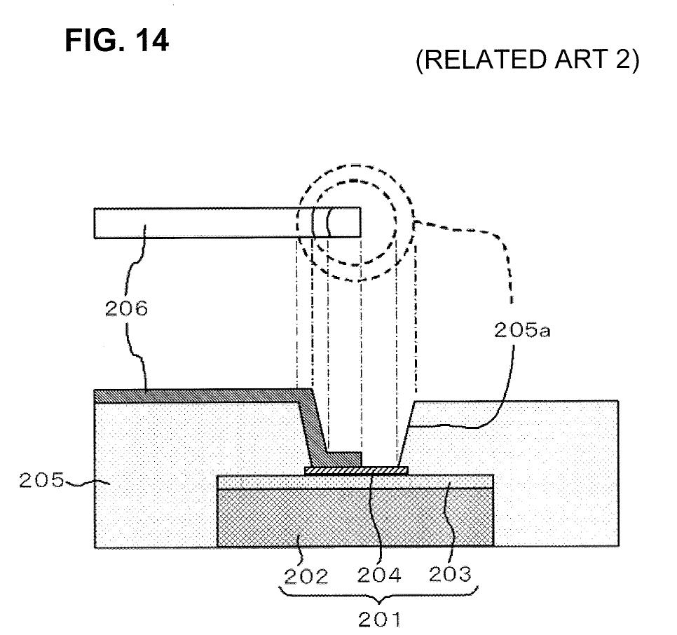

With the semiconductor device of Example 1, the electrically conductive material in the via 5a is formed to cover the entire bottom surface and the entire via sidewall. Thus, in contradistinction from the case of using an interconnection of a fine diameter, as in the related art technique 2 (see FIG. 14), the external terminal 4 is not exposed to outside on the via bottom. There is thus no risk of a liquid agent coming into touch with e.g., the external terminal 4 of the semiconductor chip 1, and hence a semiconductor device satisfactory in reliability may be obtained. Moreover, since the bottom surface as well as the sidewall sections of the via 5a is substantially entirely covered with an electrically conductive material, such as by plating, it is possible to prevent the moisture, for example, from intruding from outside, thus yielding a semiconductor device of high reliability.

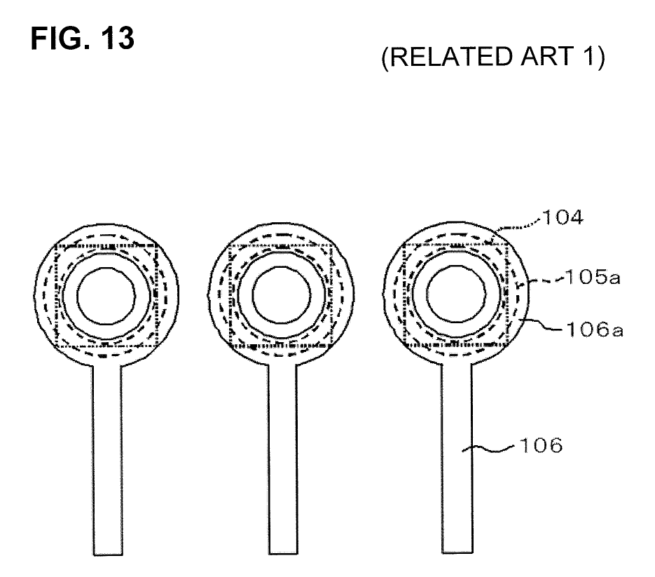

Also, in the semiconductor device of Example 1, the interconnection 6 overlying the via is lesser in diameter than the upper part of the via 5a. Moreover, the conductor has no land structure in contrast to the case of the related art technique 1 (see FIG. 13). It is thus a via diameter that governs the via pitch. The via pitch may thus be reduced down to a limit value corresponding to the sum of the via diameter and the minimum via-to-via distance, thus providing for narrow-pitch via connection (see FIG. 2). This means that, in the semiconductor device, the semiconductor chips 1 with the small pitch of the external terminals 4 may be integrated. In short, since the pitch may be reduced in general in a semiconductor chip having a larger number of terminals, a multi-chip semiconductor chip, difficult to integrate in a board in the conventional practice, may be integrated non-problematically.

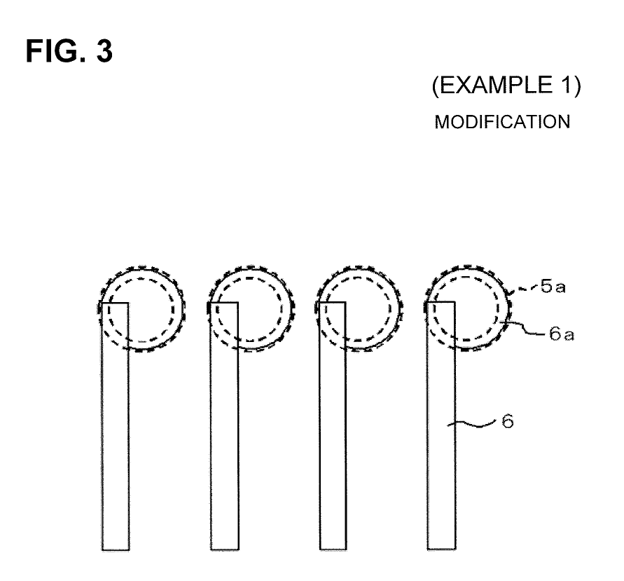

Moreover, in the semiconductor device of Example 1, the interconnection 6 is fine in diameter relative to the via 5a. In addition, the via conduction part 6a is charged in the via 5a completely or substantially completely. Thus, even in case the interconnection 6 is formed at an offset position with respect to the position of the via 5a, as shown in FIG. 3, the interconnection 6 may be electrically connected to the external terminal 4 of the semiconductor chip 1 non-problematically. There is an additional advantage that no shorting is caused between the interconnection and the neighboring vias 5a.

Further, in the semiconductor device of Example 1, the interconnection 6 and the via conduction part 6a are formed integral with each other, so that there is no interface therebetween. The interconnection 6 and the via conduction part 6a are strong in their connection strength, such that no problem is raised as regards the connection strength in the integral structure. It is observed that, in case the via conduction part 6a is initially formed and the interconnection 6 is subsequently formed, as in Comparative Example, an interface is formed between the via conduction part 6a and the interconnection 6. In such case, peel-off or the like failures may be produced, thus deteriorating the reliability.

In the semiconductor device of Example 1, the entire surfaces of the via sidewall section and the via bottom are covered by the via conduction part 6a, such that mechanical stresses in the interconnection 6 are less likely to get to the via bottom. This also helps prevent the occurrence of peel-off at the interface of the external terminal 4 of the semiconductor chip 1.

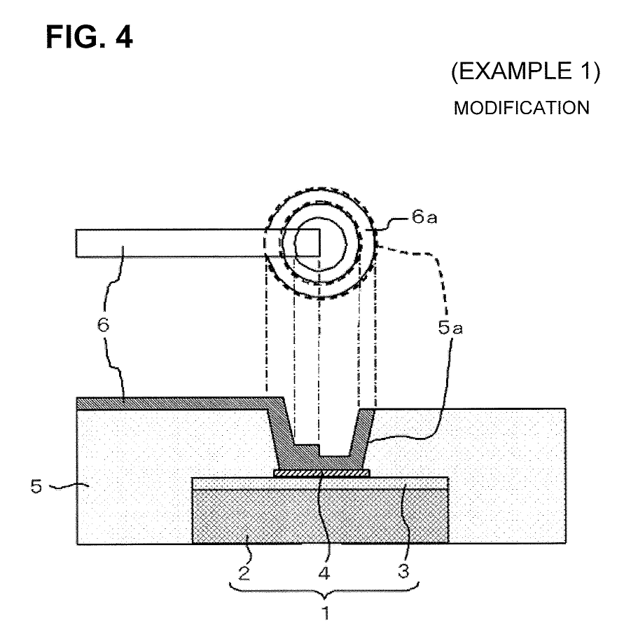

In the semiconductor device of Example 1, the inside of the via 5a may be completely filled with the via conduction part 6a, as shown in FIG. 1. Alternatively, it is not necessary that the inside of the via 5a is completely filled with the via conduction part 6a, as shown in FIG. 4, provided that substantially the entire surfaces of the via sidewall section and the via bottom are covered by the via conduction part.

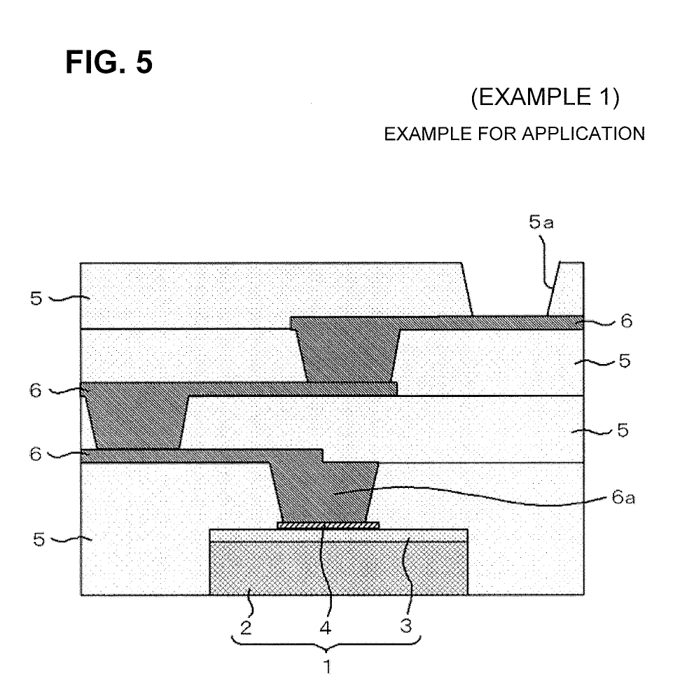

FIG. 1 shows only a single-layer interconnection structure. Alternatively, there may be a plurality of interconnections 6 and insulation layers 5 on top of the interconnection 6, as shown in FIG. 5, provided that the interconnections 6 of the respective layers connect to one another by vias. In this case, a stacked via, composed of a plurality of vias superposed together, may be formed, provided that the entire via surfaces are filled with the electrically conductive material. Hence, a semiconductor device having a stacked via of narrow pitch and high reliability may be obtained.

The method for manufacturing the semiconductor device according to Example 1 of the present invention will be described with reference to the drawings. FIGS. 6A to 6D and FIGS. 7A to 7C are cross-sectional views showing the method for manufacturing the semiconductor device of Example 1 of the present invention.

Initially, a semiconductor chip 1, carrying thereon an external terminal 4, is mounted on a support plate 8 (step A1; see FIG. 6A). It is observed that, although only one external terminal is shown, there are, in actuality, a large number of the external terminals 4.

An insulation layer 5 of a non-photosensitive resin is then formed on the support plate 8, inclusive the semiconductor chip 1, in such a manner that the semiconductor chip 1 is embedded in the insulation layer 5 (step A2; see FIG. 6B).

In forming the insulation layer 5 of the non-photosensitive resin on the semiconductor chip 1, it is not requisite that the insulation layer 5 is formed on an active surface (side of the LSI layer 3) of the semiconductor chip 1 set facing upwards. Viz., the semiconductor chip 1 may be loaded on the insulation layer 5, prepared background, so that the active surface of the semiconductor chip will face downwards. In this case, the support plate 8 may not be used.

A via 5a is then formed through the insulation layer 5, such as by laser light, until the via gets to the external terminal 4 of the semiconductor chip 1 (step A3; see FIG. 6C).

A resist layer 9 is then formed on the insulation layer 5 (step A4; see FIG. 6D). The resist layer 9 is usable in forming the interconnection and an electrically conductive material to be charged in the via, and acts as a plating resist. In forming the resist layer 9, it is important that the inside of the via 5a is not filled with the resist because an electrically conductive layer needs to be formed in the hollow space inside of the via 5a to cover the via bottom and the via sidewall. If, in the plating process step of FIG. 7B, a seed layer, not shown, is needed, such seed layer is formed before forming the resist layer 9. The seed layer may be formed by sputtering or by electroless plating.

A film-shaped resist may also be used as a resist layer 9. The resist may be classed into a varnish-like resist and a film-like resist. The film-like resist is worked in a film shape at the outset, and is bonded onto the insulation layer 5 by e.g. a laminator. Among different sorts of the film-like resist, there is a resist called a dry film resist, for example. In using the film-like resist, no resist may be allowed to be charged into the via 5a. This is made possible by suitably controlling e.g. lamination conditions for the film-like resist. By so doing, the plating process may be initiated as the inside of the via 5a is left in the hollow state, so that the inside of the hollow part may be filled with the plating material. On the other hand, if the varnish-like resist is used, the varnish will drip to fill the inside of the via when the varnish is being formed on the insulation layer. Thus, as a principle, the varnish-lie resist may not be used in the method for manufacturing the semiconductor device according to Example 1. However, if the varnish-like resist is used, but the resist layer is formed under a condition in which an air bubble is left in the via and the via thus is not filled up, such as by increasing the viscosity of the resist, the varnish-like resist may be used in the manufacturing method for the semiconductor device of Example 1.

The resist layer 9 is then subjected to patterning (step A5; see FIG. 7A). At this time, an opening part of the resist layer 9 is formed in keeping with the shape of the interconnection (6 of FIG. 7B) and the position of the via 5a. The width of the opening part engaging with the interconnection (6 of FIG. 7B) above the via 5a is to be lesser than the via upper diameter. By having the inside of the via 5a not filled at the time of forming the resist layer 9, a hollow part is formed in the via 5a when the opening part of the resist layer 9 is formed.

The opening part denotes a vacant portion of the resist layer 9. Such vacant portion may be formed by exposing to light and developing the resist layer 9. The opening part may be the same as the shape of the interconnection. The opening part is to conform to the shape of the foremost part of the interconnection which may be circular or elliptical.

The interconnection 6 and the via conduction part 6a are formed integral (solid) with each other by e.g. the plating process (step A6; see FIG. 7B). By ‘forming integral’ is meant the one-step forming of the interconnection 6 and the electrically conductive layer of the via conduction part 6a by e.g., plating, whereby the number of process steps may be reduced. By integral forming, no interface is formed between the interconnection 6 and the via conduction part 6a. The semiconductor device having high reliability may be obtained in which there is no risk of peel-off at the interface. Also, the via bottom and the via sidewall section are covered with the via conduction part 6a.

The resist layer (9 of FIG. 7B) is then removed (step A7; see FIG. 7C). It is observed that, in case the seed layer, not shown, has been formed before the step of forming the resist layer 9 of FIG. 6D, the seed layer is removed after removing the resist layer (9 of FIG. 7B). The support plate 8 then is removed to yield a semiconductor device similar to that of FIG. 1.

Certain Concrete Examples for the semiconductor device of Example 1 of the present invention will now be described. It is observed that the present invention is not restricted to the following Concrete Examples and may be modified or altered within the scope of the technical concept of the present invention.

### Concrete Example 1

An FR4 substrate was used as a support plate (8 of FIG. 6A). A semiconductor chip (1 of FIG. 6A), having an external terminal (4 of FIG. 6A), was mounted and fixed on the support plate (8 of FIG. 6A). The number of the external terminals 4 of the semiconductor chip 1 was 800. An insulation layer (5 of FIG. 6B), formed of the non-photosensitive resin film of the stage B, was stuck on the support plate (8 of FIG. 6B), carrying thereon a semiconductor chip (1 of FIG. 6B), and the resulting product was heat cured. A plurality of integral of which is shown at 5a in FIG. 6C, were opened at a pitch of 60 μm, using a UV-YAG laser, so that the vias (5a of FIG. 6C) would be formed in register with the external terminals (4 of FIG. 6C) of the semiconductor chip (1 of FIG. 6C) embedded in the insulation layer (5 of FIG. 6A). After desmearing, the size of the via (5a of FIG. 6C) was measured, and found to be 50 μm at the top and 30 μm at the bottom. A Cu seed layer, not shown, was formed by sputtering, and a resist layer (9 of FIG. 6D), formed by a dry film, was bonded with a laminator. The resist layer was exposed to light, using a mask, not shown. The mask was prepared background with an interconnection pattern of a width of 20 μm and a pitch of 60 μm, with a width of the pattern at the foremost part remaining to be 20 μm. The interconnection (6 of FIG. 7B) and the via conduction layer (6a of FIG. 7B), both of which were formed by copper plating, were then formed by development. The resist layer (9 of FIG. 7B) was then removed. Visual inspection of the so prepared semiconductor device indicated that the foremost part of the interconnection 6 reached a mid part of the via 5a. The external terminal 4 of the semiconductor chip 1 was hidden below the via conduction layer 6a and hence was not visible. Visual check of a cross-section of the sample prepared indicated that the via 5a in its entirety was filled with the via conduction part 6a. Also, the results of an electrical test conducted indicated that no shorting occurred between neighboring interconnections.

### Concrete Example 2

A semiconductor chip (1 of FIG. 6A) was mounted on the support plate (8 of FIG. 6A), as in the Concrete Example 1. An insulation layer (5 of FIG. 6B) was deposited thereon, and a via (5a of FIG. 6C) was then opened. A resist layer (9 of FIG. 6D), formed by a dry film, was then applied. A mask, not shown, which was the same as that used in the Concrete Example 1, was used, but was intentionally shifted in its position by approximately 15 μm in carrying out the light exposure. The interconnection (6 of FIG. 7B) and the via conduction layer (6a of FIG. 7B) were then formed on development. The resist layer (9 of FIG. 7B) was then removed to form the interconnection 6 offset as shown in FIG. 3. Visual check of the semiconductor device 1 prepared indicated that, although the interconnection 6 was appreciably shifted from the center of the via 5a, there was noticed no shorting between neighboring interconnections 6. Visual check of a cross-section of the sample prepared indicated that the via 5a in its entirety was filled with the via conduction part 6a.

### Comparative Example 1

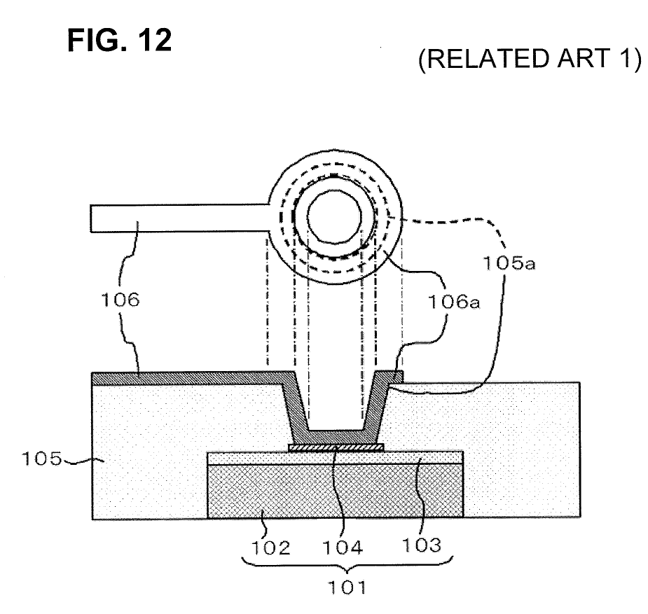

As in the Concrete Example 1, a semiconductor chip was mounted on a support plate and an insulation layer was deposited thereon. A via was then opened, and a resist layer, formed by a dry film, was applied. The resulting product was exposed to light using a mask, not shown, patterned to form an interconnection (106 of FIG. 12) and a land (106a of FIG. 12) of 50 μm at the foremost part of the interconnection, as shown in FIG. 12. After development, the land (106a of FIG. 12) and the interconnection (106 of FIG. 12) were formed. The resist layer was then removed to form the interconnection (106 of FIG. 12) having the land (106a of FIG. 12). Visual inspection of the semiconductor device fabricated indicated that shorting occurred here and there between the land (106a of FIG. 12) and the neighboring interconnection (106a of FIG. 12).

### Comparative Example 2

A semiconductor chip was prepared in the same way as in the Concrete Example 1, except using a varnish-like resist as a plating resist. Visual inspection of the semiconductor device fabricated indicated that the interconnection passed through substantially the center of the via, however, the external terminal of the semiconductor chip was exposed to outside.

In the manufacturing method for a semiconductor device according to Example 1, the plating resist layer having an opening part smaller in diameter than the upper via diameter is formed, so that connection may be with the minimum pitch allowable with the via size used. Hence, the interconnection 6 may be connected to the via 5a with a narrow pitch as shown in FIG. 2. It is observed that, with the conventional manufacturing method for the semiconductor device, an opening part is provided in the plating resist layer so that the opening part will be broader than the area of the via 105a, as shown in FIG. 13. This opening part imposes limitations on the via pitch to render it difficult to lay out the interconnection at a narrow via pitch.

In the manufacturing method for the semiconductor device according to Example 1, the via conduction part 6a is charged into the inside of the via 5a in its entirety, connection between the interconnection 6 and the via conduction part 6a may be assured, as shown in FIG. 3, even in case the opening part of the resist layer 9 has become offset in its position.

Moreover, in the manufacturing method for the semiconductor device according to Example 1, the interconnection 6 and the via conduction part 6a are formed integral by the plating process step. Thus, the manufacturing process may be simplified in comparison with the method of separately preparing the interconnection and the via conduction part. In addition, there is no interface between the interconnection and the via conduction part. There is thus no risk of pee-off between the interconnection and the via conduction part, thus assuring improved connection strength between the interconnection and the via conduction part. Hence, the semiconductor device obtained may be high in connection reliability.

In addition, in the manufacturing method for the semiconductor device according to Example 1, the bottom and the sidewall section of the via 5a are covered in their entirety by the via conduction part 6a. Hence, the portion of the semiconductor chip 1 lying at the via bottom is not exposed to outside, so that there is no risk of the liquid drug being in contact with the surface of the semiconductor chip 1. The semiconductor device produced may thus be high in reliability.

Furthermore, in the manufacturing method for the semiconductor device according to Example 1, the stacked vias of high reliability may be formed if, in forming a plurality of the insulation layers 5 and a plurality of layers of the interconnections 6, as shown in FIG. 5, each via is completely filled with the via conduction part 6a. Even though the via is not completely filled with the via conduction parts 6a, the surfaces of the via bottom and the via sidewall section are covered in their entirety, as shown in FIG. 4. There is thus no risk of exposure to outside of the external terminal 4 of the semiconductor chip 1 or of liquid seeping through the interfacing region.

### Example 2

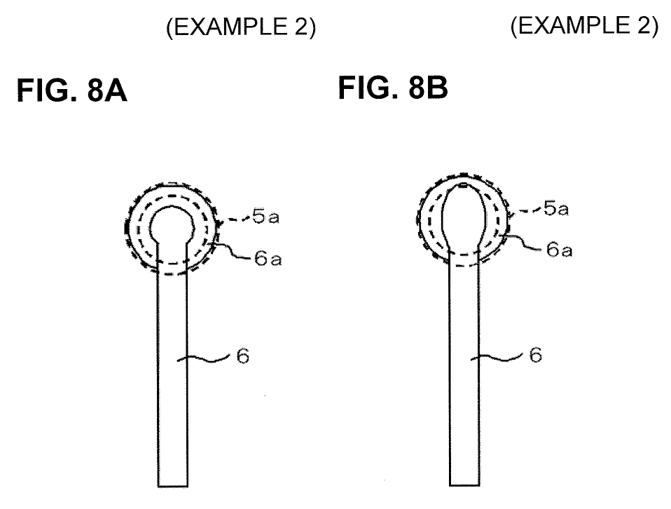

A semiconductor device according to Example 2 of the present invention will now be described with reference to the drawings. FIGS. 8A and 8B depict schematic plan views showing the position relationships between the interconnection and the via of the semiconductor device according to Example 2 of the present invention.

In the semiconductor device according to Example 2, the via conduction part 6a at the distal end of the interconnection 6 is circular (see FIG. 8A) or elliptical (see FIG. 8B) in profile, with the diameter of the circle or the long diameter of the ellipsis being smaller than the upper via diameter. Specifically, the diameter or the long diameter of the circle or the ellipsis at the distal end part of the interconnection 6 is not less than one-third and not larger than two-thirds of the upper via diameter. In other respects, the present Example is the same as the Example 1 (see FIG. 1).

In the manufacturing method of the semiconductor device according to Example 2, the profile of the opening part of the resist layer (9 of FIG. 7A) overlying the via (5a of FIG. 7A) in the step A5 of Example 1 (see FIG. 7A) is the shape of a circle or an ellipsis. The diameter of the circle or the long diameter of the ellipsis is to be less than the diameter of the upper via part. In addition, the diameter or the long diameter of the circle or the ellipsis of the opening part of the resist layer (9 of FIG. 7A) is set so as to be not less than one-third and not larger than two-thirds of the upper via diameter. Otherwise, the process steps are similar to those of Example 1 (see FIGS. 6A to 6D and 7A to 7C).

The distal end of the interconnection 6 being circular or elliptical in profile means that the portion of the via conduction part 6a at the distal end part of the interconnection 6 is circular or elliptical in profile.

With the semiconductor device according to Example 2, the meritorious results similar to those obtained with Example 1 may be obtained. Additionally, since the interconnection 6 is smaller in width than the upper via diameter, connection may be at a narrow via pitch. Moreover, since the contact area may be broader with a high yield, the semiconductor device obtained may be higher in reliability. Further, the semiconductor device may be improved in symmetry in comparison with the device with a rectangular interconnection, and the mechanical stress may be evenly distributed to provide for higher reliability.

With the semiconductor device according to Example 2, the meritorious results similar to those obtained with Example 1 may be obtained. Additionally, since the diameter or the long diameter of the circle or the ellipsis of the opening part of the resist layer (9 of FIG. 7A) is set so as to be smaller than the upper via diameter, the via pitch may be reduced to the limit value imposed by the via size as shown in FIG. 2. In case of offset in light exposure shown in FIG. 3, shorting with neighboring interconnections or vias may be suppressed from occurring. Since the opening part is reduced in size, the inside of the via is not filled with a resist material to advantage. With the circular or elliptical shape of the opening part of the resist layer (9 of FIG. 7A), the distance from the edge of the opening part to the via sidewall section may be reduced to improve the covering power of the plating material for the via sidewall section. In case of the elliptically shaped opening part, it is possible to reduce the connection length to the neighboring interconnection as the broad area of the opening part is kept.

### Example 3

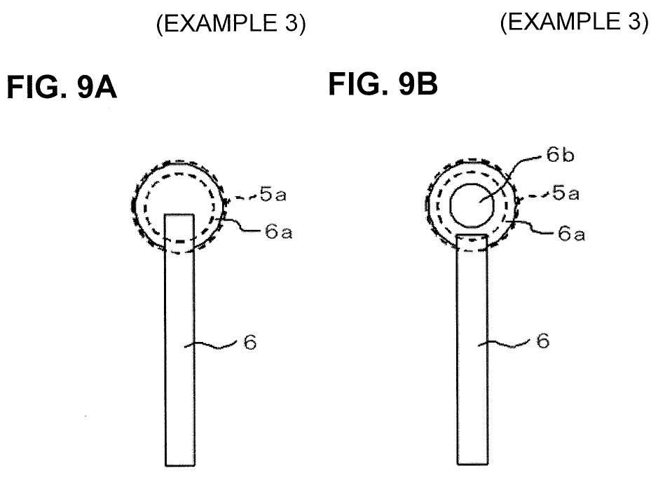

A semiconductor device according to Example 3 of the present invention will now be described with reference to the drawings. FIGS. 9A and 9B depict schematic plan views showing the position relationships between the interconnection and the via of the semiconductor device according to Example 3 of the present invention.

In the semiconductor device of Example 3, the interconnection 6 is not extended to the center of the via 5a. Otherwise, the Example 3 is similar to the Example 1 shown in FIG. 1.

In the manufacturing method for the semiconductor device according to Example 3, the opening part of the resist layer (9 of FIG. 7A) above the via (5a of FIG. 7A) is not extended in the step A5 of Example 1 (see FIG. 7A) to the center of the via 5a. Otherwise, the process steps are similar to those of Example 1 (see FIGS. 6A to 6D and 7A to 7C).

With the semiconductor device according to Example 3, the meritorious results similar to those obtained with Example 1 may be obtained. In addition, connection may be with a narrow via pitch. With the manufacturing method for the semiconductor device according to Example 3, not only the meritorious results similar to those of Example 1 may be obtained, but also it is possible to prevent that the via 5a is filled with the material of the resist layer (9 of FIG. 7A).

### Example 4

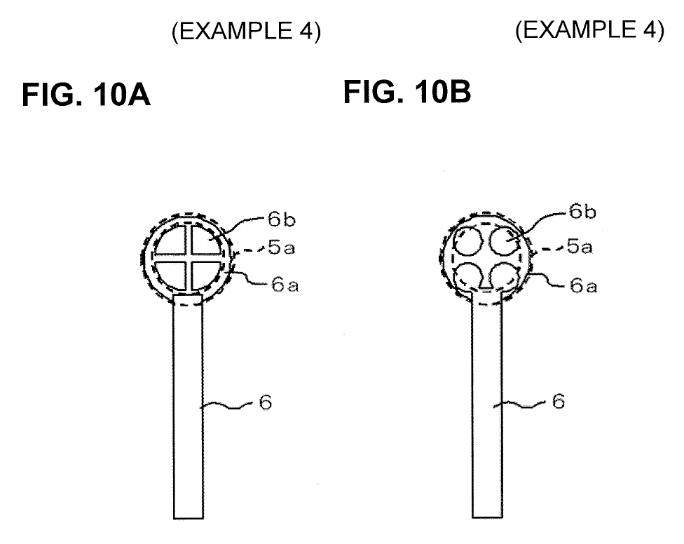

A semiconductor device according to Example 4 of the present invention will be described with reference to the drawings. FIGS. 10A and 10B depict schematic plan views showing the position relationships between the interconnection and the via of the semiconductor device according to Example 4 of the present invention.

In the semiconductor device of Example 4, one or more protrusions 6b are formed integral with the via conduction part 6a in isolation from the distal end of the interconnection 6. The interconnection 6 may be connected to one or some of the protrusions 6b (see FIG. 10B). Otherwise, the present Example is similar to Example 1 (see FIG. 1).

In the manufacturing method for the semiconductor device according to Example 4, the shape of the opening part of the resist layer (9 of FIG. 7A) above the via (5a of FIG. 7A) in the step A5 of Example 1 (see FIG. 7A) is such a shape in which the pattern for the protrusion 6b is isolated from that for the interconnection 6. Otherwise, the process steps of the present Example are similar to those of Example 1 (see FIGS. 6A to 6D and 7A to 7C).

With the semiconductor device of Example 4, the mechanical stress in the via or the like may be relieved to provide a semiconductor device of high reliability. With the manufacturing method for the semiconductor device of Example 4, the shape of the opening part of the resist layer (9 of FIG. 7A) above the via (5a of FIG. 7A) is such a shape in which the pattern for the protrusion 6b is isolated from that for the interconnection 6. Thus, the resist layer (9 of FIG. 7A) operates as support to prevent intrusion of the resist material into the inside of the via 5a.

### Example 5

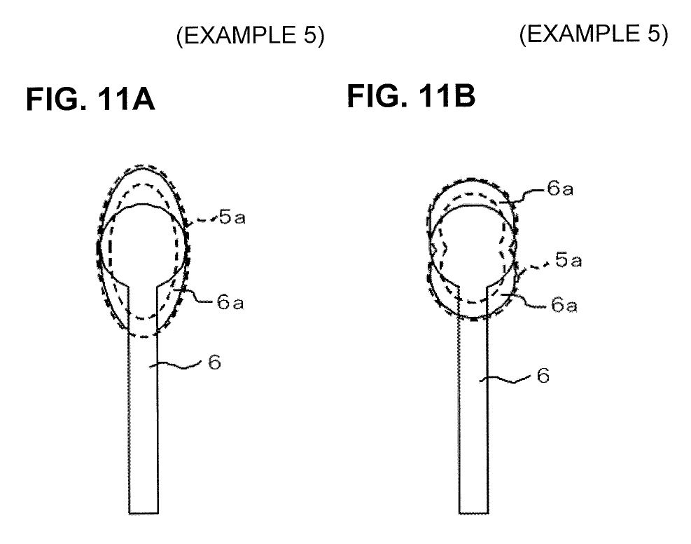

A semiconductor device according to Example 5 of the present invention will be described with reference to the drawings. FIGS. 11A and 11B depict schematic plan views showing the position relationships between the interconnection and the via of the semiconductor device according to Example 5 of the present invention.

In the semiconductor device according to Example 5, the plan shape of the via 5a is elliptical (see FIG. 11A) or an oval-shaped, or composed of a plurality of circles or partial circles concatenated together (see FIG. 11B). The distal end of the interconnection 6 at the via conduction part 6a is circular or oval-shaped and its diameter is set so as to be equal to or lesser than the diameter or the long diameter of the circle or the ellipsis. Part of the distal end shape of the interconnection 6 may be deviated from the area of the via conduction part 6a as long as the distal end shape is within the extent of the width along the transverse direction of the via conduction part 6a. A plurality of protrusions (6b of FIG. 4) may be formed above the via conduction part 6a in separation from the distal end of the interconnection 6, as in Example 4 (see FIGS. 10A and 10B). Otherwise, the preset Example is similar to Example 1 (see FIG. 1).

In the manufacturing method for the semiconductor device according to Example 5, the plan shape of the via 5a is elliptical (see FIG. 11A) or is formed by a plurality of circles or partial circles concatenated together (see FIG. 11B) in the step A3 of Example 1 (see FIG. 6C). Also, in the step A5 of Example 1 (see FIG. 7A), the shape of the opening part of the resist layer (9 of FIG. 7A) overlying the via (5a of FIG. 7A) is set so as to be circular or elliptical, and the via diameter is set so as to be equal to or lesser than the diameter of the circle or the short diameter of the ellipsis. In other respects, the process steps of the present Example are similar to those of Example 1 (see FIGS. 6 and 7).

With the semiconductor device according to Example 5, such a semiconductor device that has high tolerability against position shift in the direction along the interconnection and a high yield may be obtained. A plurality of protrusions (6b of FIGS. 10A and 10B) are formed in separation from the distal end of the interconnection 6 so that the mechanical stress is suitably distributed to improve the reliability of the semiconductor device. The distal end of the interconnection 6 means the portion of the interconnection overlying the via 5a. Since this portion is small in size, the via arraying pitch may be reduced to a size limit imposed by the via size. Moreover, in the manufacturing method for the semiconductor device according to Example 5, the tolerability against the shifting along the direction of the interconnection may be increased to advantage in case the via 5a is formed by an ellipsis, a circle or a plurality of circles or partial circles.

Among the utilization examples of the present invention, there is a semiconductor device having a multi-pin semiconductor chip enclosed in a substrate. Such semiconductor device may be used in, for example, a mobile phone or in a variety of electrical appliances.

The particular exemplary embodiments or examples may be modified or adjusted within the gamut of the entire disclosure of the present invention, inclusive of claims, based on the fundamental technical concept of the invention. Further, a large variety of combinations or selection of elements disclosed herein may be made within the framework of the claims. That is, the present invention may comprehend various modifications or corrections that may occur to those skilled in the art in accordance with and within the gamut of the entire disclosure of the present invention, inclusive of claim and the technical concept of the present invention.

### EXPLANATIONS OF SYMBOLS

1, 101, 201 semiconductor chips
2, 102, 202 semiconductor layers
3, 103, 203 LSI layers
4, 104, 204 external terminals
5, 105, 205 insulation layers
5a, 105a, 205a vias
6, 106, 206 interconnections (wiring traces)
6a via conduction part
6b protrusion
8 support plate
9 resist layer
106a land
301 multiplayer wiring board
302 insulation layer
303 conductor interconnection layer
304 via hole conductor

What is claimed is:

1. A semiconductor device in which an insulation layer is formed on a semiconductor chip having a plurality of external terminals, a plurality of interconnections are formed on said insulation layer, and in which said external terminals and those interconnections that are coordinated to the external terminals are electrically connected to each other through a plurality of vias formed in said insulation layer; wherein
a via conduction part is formed so that, in the inside of said via, said via conduction part covers the entire surfaces of a bottom and a sidewall section of said via; said via conduction part being formed integral with said interconnection;
a portion of said interconnection overlying said via being smaller in size than a diameter of an upper part of said via.

2. The semiconductor device according to claim 1, wherein a peripheral part of said via on said insulation layer is devoid of a land.

3. The semiconductor device according to claim 1, wherein said via conduction part completely fills the inside of said via.

4. The semiconductor device according to claim 1, wherein
the portion of said interconnection overlying said via is circular or elliptical; with a diameter or long diameter being lesser than the diameter of the upper part of said via.

5. The semiconductor device according to claim 4, wherein
the diameter of said circle or the long diameter of said ellipsis is not less than one-third and not larger than two-thirds of the diameter of said upper part of said via.

6. The semiconductor device according to claim 1, wherein
a distal end of said interconnection overlying said via is not extended to a center of said via.

7. The semiconductor device according to claim 1, wherein said via conduction part includes one or more protrusions formed integral therewith; said one or more protrusions being separated from a distal end of said interconnection overlying said via.

8. The semiconductor device according to claim 1, wherein said via has a shape of ellipsis, an oval shape or a plurality of circles or partial circles concatenated together.

9. A method for manufacturing a semiconductor device comprising:
forming an insulation layer on a semiconductor chip having a plurality of external terminals;
forming a plurality of vias in said insulation layer for connecting to said external terminals;
forming a resist layer having an opening part for an interconnection on said insulation layer; a width of said opening part for said interconnection overlying said via being lesser than a diameter of an upper part of said via; and
forming a via conduction part and said interconnection integral with each other on said insulation layer, using said resist layer as a mask, so that said via conduction part and said interconnection will cover the bottom surface and the sidewall sections of said via.

10. The manufacturing method for the semiconductor device according to claim 9, wherein
a film-like resist is used in said resist layer forming step to form said resist layer.

11. The manufacturing method for the semiconductor device according to claim 9, wherein
a portion of said interconnection overlying said via is circular or elliptical; with a diameter or the long diameter being lesser than a diameter of the upper part of said via.

12. The manufacturing method for the semiconductor device according to claim 11, wherein
said opening part for said interconnection in said resist layer overlying said via is formed so that the diameter of said circle or the diameter of said ellipses will be not less than one-third and not more than two-thirds of the diameter of the upper part of said via.

13. The manufacturing method for the semiconductor device according to claim 9, wherein
a distal end of said interconnection overlying said via is not extended to a center of said via.

14. The manufacturing method for the semiconductor device according to claim 9, wherein
in said step of forming said resist layer, the opening part for said interconnection of said resist layer overlying said via is formed so that said opening part will be isolated from an opening part connecting to the opening part for said interconnection of said resist layer on said insulation layer.

15. The manufacturing method for the semiconductor device according to claim 9, wherein
in said step of forming said resist layer, the opening part for said interconnection of said resist layer overlying said via is formed so as to present a plurality of regions.

16. The manufacturing method for the semiconductor device according to claim 9, wherein
in said step of forming said via, said via is formed so that a plan shape thereof will be a shape of an ellipsis, that of an oval or that of a plurality of circles or partial circles concatenated together.
